(19) United States
(12) Patent Application Publication
(10) Pub. No.: US 2009/0155975 A1
(43) Pub. Date: Jun. 18, 2009

(54) METHOD FOR MANUFACTURING METAL-INSULATOR-METAL CAPACITOR OF SEMICONDUCTOR DEVICE

(75) Inventor: Jeong Ho PARK, Icheon-si (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/266,399

(22) Filed: Nov. 6, 2008

(30) Foreign Application Priority Data
Dec. 17, 2007 (KR) 10-2007-0132141

(51) Int. Cl. H01L 21/02

(52) U.S. Cl. 438/393; 257/E21.008

(57) ABSTRACT

A method for manufacturing a metal-insulator-metal capacitor of a semiconductor device method for manufacturing a semiconductor device. In one example embodiment, a method for manufacturing a semiconductor device includes various steps. First, a logic metal and a capacitor lower metal is formed on a first insulating film that is formed on a semiconductor substrate. Next, a portion of the capacitor lower metal is selectively etched to a predetermined depth. Then, a second insulating film is formed over an entire upper surface of the logic metal, the first insulating film, and the capacitor lower metal. Next, a capacitor upper metal is formed on the second insulating film in a region corresponding to the etched portion of the capacitor lower metal. Finally, a third insulating film is formed on an entire upper surface of the second insulating film and the capacitor upper metal.

### CROSS-REFERENCE TO A RELATED APPLICATION

This application claims the benefit of Korean Patent Application No. 10-2007-0132141, filed on Dec. 17, 2007 which is hereby incorporated by reference as if fully set forth herein.

### BACKGROUND

1. Field of the Invention

Embodiments of the present invention relate to methods for manufacturing a semiconductor device, and more particularly, to methods for manufacturing a metal-insulator-metal (MIM) capacitor of a semiconductor device.

2. Description of the Related Art

A merged memory logic (MML) has a structure in which a memory cell array and an analog circuit or a peripheral circuit are integrated into a single chip. MMLs can enhance multimedia functionality, thereby achieving relatively high integration and high-speed operation in semiconductor devices. Research is ongoing to realize a capacitor having a high capacitance in an analog circuit requiring high-speed operation.

In the case of a capacitor having a polysilicon-insulator-polysilicon (PIP) structure, conductive polysilicon is used for the upper and lower electrodes of the capacitor. However, oxidation may occur at an interface between the upper electrode and a dielectric thin film and at an interface between the lower electrode and the dielectric thin film, thus forming a natural oxide film. However, this results in a reduction in the total capacitance of the capacitor. A reduction in total capacitance may also occur due to a depletion region being formed in the polysilicon layer. For this reason, PIP capacitors may be unsuitable for high-speed and high-frequency operations.

An MIM capacitor with both upper and lower electrodes formed using a metal layer has been proposed in order to solve this reduction in total capacitance. MIM capacitors are mainly used in high-performance semiconductor devices because they exhibit a low specific resistance and do not exhibit a parasitic capacitance caused by internal depletion.

Generally, a capacitor lower metal is formed simultaneously with a lower metal line. Subsequently, a capacitor insulating film and a capacitor upper metal are formed over the capacitor lower metal to complete the formation of the MIM capacitor.

FIGS. 1A and 1B are sectional views illustrating a prior art method for forming a prior art MIM capacitor. As shown in FIG. 1A, the MIM capacitor includes a first insulating film 10, a logic 15 formed in the first insulating film 10, a second insulating film 20 formed on the first insulating film 10 and the logic 15, a lower metal layer 25 formed on the second insulating film 20, a third insulating film 30 formed on the lower metal layer 25, and an upper metal layer 35 formed on the third insulating film 30.

As shown in FIG. 1A, the prior art MIM capacitor has a step structure formed near the logic 15. For this reason, as shown in FIG. 1B, when an interlayer insulating film 40 is formed in order to subsequently form a metal line for the MIM capacitor, the insulating film 40 cannot have a planarized surface due to the step structure. Consequently, a planarizing process, such as a chemical mechanical polishing (CMP) process, must be performed after the formation of the MIM capacitor prior to performing subsequent manufacturing process(es), such as a process for forming a metal line for the MIM capacitor for example. However, this additional planarizing process increases process costs.

### SUMMARY OF EXAMPLE EMBODIMENTS

In general, example embodiments of the present invention relate to methods for manufacturing a metal-insulator-metal capacitor of a semiconductor device. Some example embodiments of the present invention eliminate the need for one or more planarizing processes by eliminating a step structure in the MIM capacitor, thereby achieving a reduction in the manufacturing costs of the semiconductor device.

In one example embodiment, a method for manufacturing a semiconductor device includes various steps. First, a logic metal and a capacitor lower metal are formed on a first insulating film that is formed on a semiconductor substrate. Next, a portion of the capacitor lower metal is selectively etched to a predetermined depth. Then, a second insulating film is formed over an entire upper surface of the logic metal, the first insulating film, and the etched capacitor lower metal. Next, a capacitor upper metal is formed on the second insulating film in a region corresponding to the etched portion of the etched capacitor lower metal. Finally, a third insulating film is formed on an entire upper surface of the second insulating film and the capacitor upper metal.

In another example embodiment, a method for manufacturing a semiconductor device includes various steps. First, a logic metal and a capacitor lower metal are formed on a first insulating film that is formed on a semiconductor substrate. Next, a portion of the capacitor lower metal is selectively etched to a predetermined depth. Then, a second insulating film is formed over an entire upper surface of the logic metal, the first insulating film, and the etched capacitor lower metal. Next, a capacitor upper metal is formed on the second insulating film in a region corresponding to the etched portion of the etched capacitor lower metal. Then, an interlayer insulating film is formed over an entire upper surface of the second insulating film and the capacitor upper metal. Next, the interlayer insulating film and the second insulating film are selectively etched, thereby forming a first contact hole through which a portion of the capacitor upper metal is exposed, and a second contact hole through which a non-etched portion of the etched capacitor lower metal is exposed. Finally, the first and second contact holes are filled in with a conductive material, thereby forming portions of a metal line.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Aspects of example embodiments of the present invention will become apparent from the following detailed description of example embodiments given in conjunction with the accompanying drawings, in which:

FIGS. 1A and 1B are sectional views illustrating a prior art method for forming a general metal-insulator-metal (MIM) capacitor;

FIGS. 2A-2C are sectional views illustrating an example method for manufacturing an MIM capacitor; and

FIGS. 3A-3F are sectional views illustrating an example process for forming an upper metal line on the MIM capacitor of FIG. 2C.

### DETAILED DESCRIPTION OF EXAMPLE EMBODIMENTS

In general, example embodiments of the present invention relate to methods for manufacturing a metal-insulator-metal (MIM) capacitor of a semiconductor device. In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

### I. First Example Method For Manufacturing An MIM Capacitor

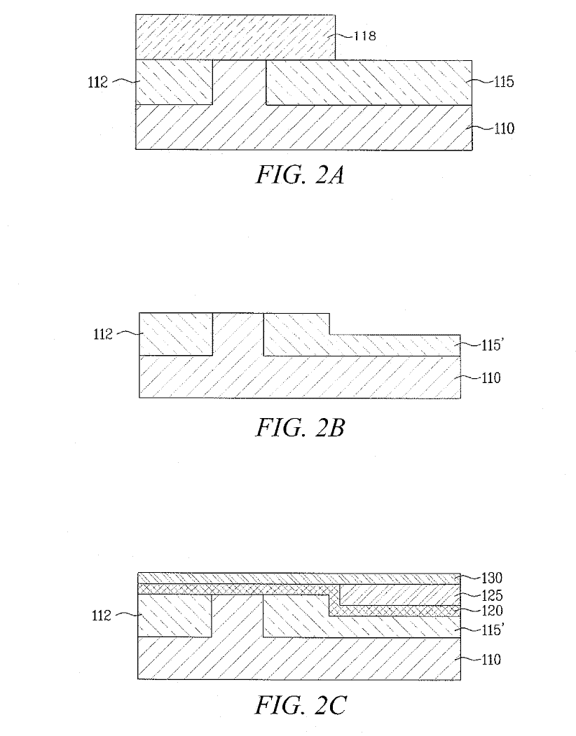

FIGS. 2A-2C are sectional views illustrating an example method for manufacturing an MIM capacitor. As disclosed in FIG. 2A, during the manufacturing of the example MIM capacitor, a logic metal 112 and a capacitor lower metal 115 are simultaneously deposited on a first insulating film 110 that is formed on a semiconductor substrate (not shown). The capacitor lower metal 115 may be made of aluminum or copper, for example. A first photoresist pattern 118 is then formed on the logic metal 112, the first insulating film 110, and a portion of the capacitor lower metal 115.

As disclosed in FIG. 2B, a portion of the capacitor lower metal 115 is next etched to a predetermined depth using the first photoresist pattern 118 as a mask. For example, the capacitor lower metal 115 may be etched to a depth corresponding to about half of the thickness of the capacitor lower metal 115, resulting in an etched capacitor lower metal 115′. The first photoresist pattern 118 is then removed.

As disclosed in FIG. 2C, a second insulating film 120 is next deposited over the entire upper surface of the logic metal 112, the first insulating film 110, and the etched capacitor lower metal 115′ such that the second insulating film 120 covers both the upper surface of the logic metal 112 and the upper surface of the etched capacitor lower metal 115′. The second insulating film 120 may comprise a nitride film, for example. A conductive material, such as a copper or titanium/titanium nitride film for example, is then deposited over the second insulating film 120. A chemical mechanical polishing (CMP) process is then performed to planarize the deposited conductive material, to thus form a capacitor upper metal 125. Thus, the capacitor upper metal 125 may be formed over the etched portion of the etched capacitor lower metal 115′, separated only by the second insulating film 120. Where the capacitor upper metal 125 is made of copper, the third insulating film 130 functions as an anti-diffusion film for the capacitor upper metal 125.

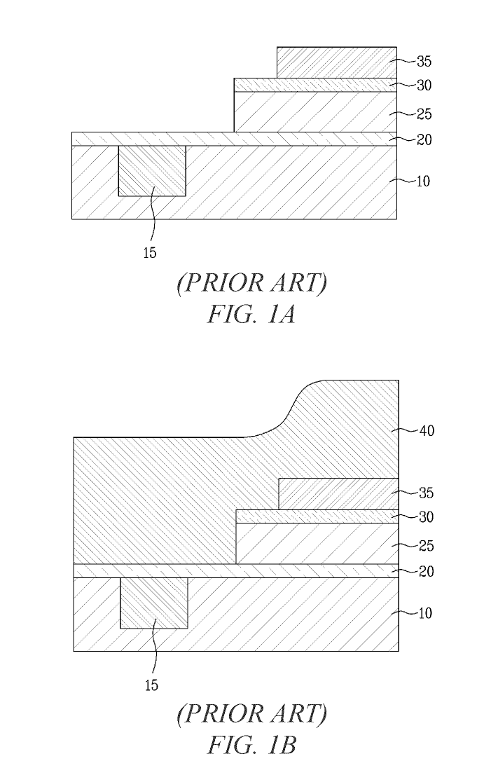

Subsequently, a third insulating film 130 is deposited on an entire upper surface of the second insulating film 120 and the capacitor upper metal 125. Thus, as disclosed in FIG. 2C, the etched capacitor lower metal 115′, the second insulating film 120, and the capacitor upper metal 125 form an MIM capacitor that does not include a step structure as does the prior art MIM capacitor shown in FIGS. 1A and 1B. Accordingly, subsequent processes can be performed on the third insulating film 130 without the need for an additional intervening planarizing process due to a step structure. As a result, the number of process steps is reduced, thereby resulting in a reduction in process costs.

### I.A. First Example Method for Manufacturing an Upper Metal Line

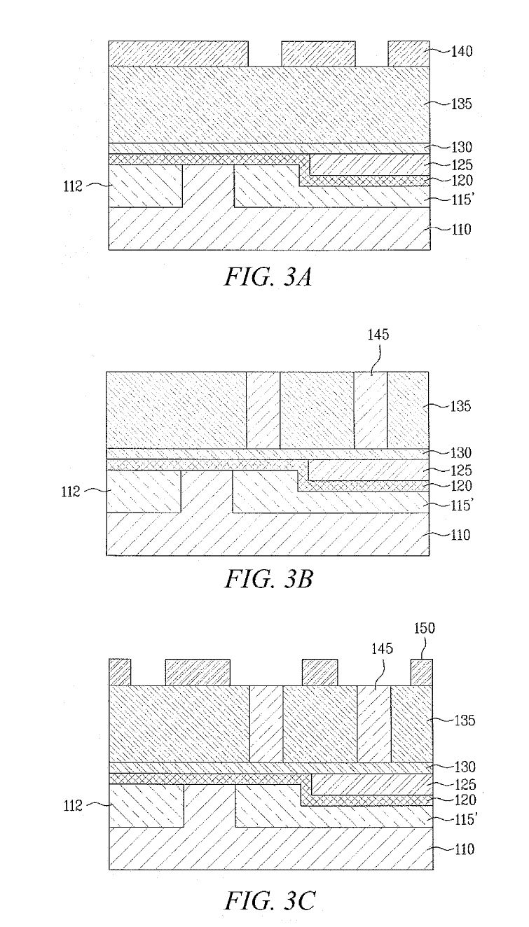

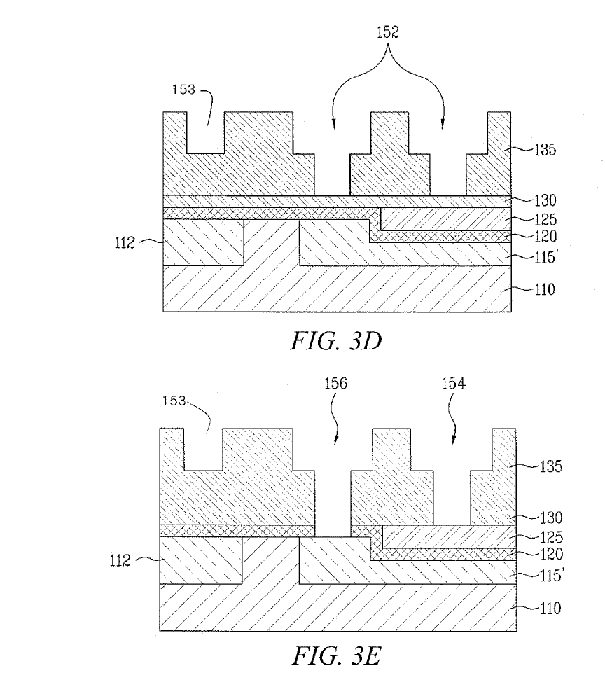

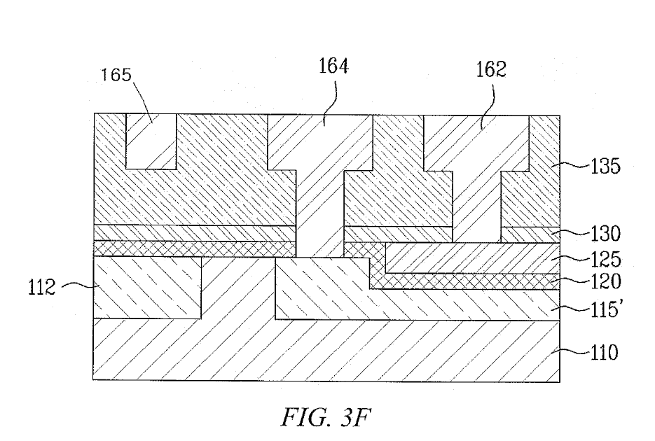

FIGS. 3A-3F are sectional views illustrating an example process for forming an upper metal line on the example MIM capacitor disclosed of FIG. 2C. With reference first to FIG. 3A, an interlayer insulating film 135 is first formed over the third insulating film 130. A second photoresist pattern 140 is then formed on the interlayer insulating film 135. The second photoresist pattern 140 includes openings positioned over a non-etched portion of the etched capacitor lower metal 115′ and over a portion of the capacitor upper metal 125. Using the second photoresist pattern 140 as an etch mask, the interlayer insulating film 135 is next etched until the third insulating film 130 is exposed resulting in a first hole corresponding to the portion of the capacitor upper metal 125 and a second hole corresponding to a non-etched portion of the etched capacitor lower metal 115′. The second photoresist pattern 140 is then removed. As disclosed in FIG. 3B, a sacrificial photoresist 145 is next filled in the first and second holes.

As disclosed in FIGS. 3C and 3D, a third photoresist pattern 150 is next formed on the interlayer insulating film 135. Using the third photoresist pattern 150 as an etch mask, the sacrificial photoresist 145 and portions of the interlayer insulating film 135 are etched forming etched portions 152, as disclosed in FIG. 3D. A third hole 153 for an upper metal line associated with the logic metal 112 is also formed. The third photoresist pattern 150 is then removed. As disclosed in FIG. 3E, the third insulating film 130 and the second insulating film 120 are next etched to form a first contact hole 154 through which the capacitor upper metal 125 is exposed, and a second contact hole 156 through which a non-etched portion of the etched capacitor lower metal 115′ is exposed.

As disclosed in FIG. 3F, a metal material is filled in the first and second contact holes 154 and 156, to form plugs 162 and 164. The plugs 162 and 164 function as contacts for the upper metal line (not shown) which is subsequently formed on the plugs 162 and 164. A metal material is also filled in the third hole 153 to form a plug 165.

### I.B. Second Example Method for Manufacturing an Upper Metal Line

Although the use of the sacrificial photoresist 145 has been described in connection with the formation of the contact holes 154 and 156, in some example embodiments the formation of the contact holes 154 and 156 may be achieved without using the sacrificial photoresist 145. A second example embodiment of a process for forming an upper metal line on the example MIM capacitor disclosed of FIG. 2C that eliminates the use of the sacrificial photoresist 145 will now be described.

As disclosed in FIG. 3A, after the formation of the interlayer insulating film 135, the second photoresist pattern 140 is formed on the interlayer insulating film 135 that includes openings positioned over a non-etched portion of the etched capacitor lower metal 115′ and the capacitor upper metal 125. As disclosed in FIG. 3B, using the second photoresist pattern 140 as an etch mask, the interlayer insulating film 135 is next etched until the third insulating film 130 is exposed, thus forming the first hole corresponding to the portion of the capacitor upper metal 125 and the second hole corresponding to the non-etched portion of the etched capacitor lower metal 115′. Thereafter, the second photoresist pattern 140 is removed.

As disclosed in FIG. 3E, after the removal of the second photoresist pattern 140, the third insulating film 130 and the second insulating film 120 are next etched to form the first contact hole 154 through which a portion of the capacitor upper metal 125 is exposed, and the second contact hole 156 through which the non-etched portion of the capacitor lower metal 115′ is exposed.

In this second example embodiment, the capacitor upper metal 125 is not etched. Only the portion of the second insulating film 120 arranged beneath the second hole 156 is selectively etched. Finally, a metal material is filled in the first and second contact holes 154 and 156, to form the plugs 162 and 164, which will function as contacts for the upper metal line (not shown), as disclosed in FIG. 3F. The upper metal line (not shown) may then be formed on the plugs 162 and 164.

### II. Second Example Method for Manufacturing an MIM Capacitor

A second example method for forming an MIM capacitor and an upper metal line will now be described. First, the process steps described above with reference to FIGS. 2A to 2C are performed. The capacitor upper metal 125 is made of a titanium or titanium nitride metal. Accordingly, it is unnecessary to use an anti-diffusion film upon subsequently forming plugs for the metal line. Thus, the third insulating film 130 shown in FIG. 2C is not formed in this second example method.

An interlayer insulating film 135 is formed over the entire upper surface of the second insulating film 120 and the capacitor upper metal 125 without an intervening third insulating film 130. The interlayer insulating film 135 and the second insulating film 120 are then selectively etched to form a first contact hole 154 through which a portion of the capacitor upper metal 125 is exposed, and a second contact hole 156 through which an non-etched portion of the etched capacitor lower metal 115′ is exposed. A metal material is filled in the first and second contact holes 154 and 156, to form plugs 162 and 164 that functions as contacts for an upper metal line (not shown).

In detail, the contact holes 154 and 156 may be formed as follows. A photoresist pattern 140 and/or 150 is formed on the interlayer insulating film 135, in order to expose the non-etched portion of the etched capacitor lower metal 115′ and a portion of the capacitor upper metal 125.

Using the photoresist pattern 140 and/or 150 as an etch mask, the interlayer insulating film 135 and second insulating film 120 are selectively etched, thus forming the first contact hole 154 through which a portion of the capacitor upper metal 125 is exposed, and the second contact hole 156 through which a non-etched portion of the etched capacitor lower metal 115′ is exposed.

Although example embodiments of the present invention have been shown and described, various modifications and variations might be made to these example embodiments. The scope of the invention is therefore defined in the following claims and their equivalents.

What is claimed is:

1. A method for manufacturing a semiconductor device, comprising:
forming a logic metal and a capacitor lower metal on a first insulating film that is formed on a semiconductor substrate;
selectively etching a portion of the capacitor lower metal to a predetermined depth;
forming a second insulating film on an entire upper surface of the logic metal, the first insulating film, and the etched capacitor lower metal;
forming a capacitor upper metal on the second insulating film in a region corresponding to the etched portion of the capacitor lower metal; and
forming a third insulating film on an entire upper surface of the second insulating film and the capacitor upper metal.

2. The method according to claim 1, further comprising;
forming an interlayer insulating film on the third insulating film;
sequentially etching the interlayer insulating film, the third insulating film, and the second insulating film, thereby forming a first contact hole through which a portion of the capacitor upper metal is exposed, and a second contact hole through which a portion of the capacitor lower metal is exposed; and
filling in the first and second contact holes with a conductive material, thereby forming portions of a metal line.

3. The method according to claim 2, wherein the step of forming the first and second contact holes comprises:
forming a photoresist pattern on the interlayer insulating film, the photoresist pattern including openings positioned over a non-etched portion of the etched capacitor lower metal and over a portion of the capacitor upper metal;
etching the interlayer insulating film using the photoresist pattern as an etch mask until the third insulating film is exposed, thereby forming a first hole corresponding to the portion of the capacitor upper metal and a second hole corresponding to the non-etched portion of the capacitor lower metal; and
etching the exposed third insulating film within the first and second holes, and etching the exposed second insulating film within the second hole, thereby forming the first contact hole through which the portion of the capacitor upper metal is exposed, and the second contact hole through which the non-etched portion of the etched capacitor lower metal is exposed.

4. The method according to claim 1, wherein the step of forming the logic metal and the capacitor lower metal comprises:
depositing the logic metal and the capacitor lower metal on the first insulating film in the same process without forming a step structure.

5. The method according to claim 1, wherein the step of forming the second insulating film comprises:
forming a photoresist pattern on the capacitor lower metal;
etching a portion of the capacitor lower metal to a depth corresponding to about half of the thickness of the capacitor lower metal using the photoresist pattern as an etch mask;
removing the photoresist pattern; and
depositing the second insulating film over an entire upper surface of the logic metal, the first insulating film, and the etched capacitor lower metal.

6. The method according to claim 1, wherein the step of forming the capacitor upper metal comprises:
depositing a conductive material over the second insulating film; and
planarizing the conductive material using a chemical mechanical polishing (CMP) process.

7. The method according to claim 6, wherein the capacitor upper metal comprises copper.

8. The method according to claim 1, wherein the capacitor lower metal comprises aluminum or copper.

9. The method according to claim 1, wherein the second insulating film comprises a nitride film.

10. A method for manufacturing a semiconductor device, comprising:
forming a logic metal and a capacitor lower metal on a first insulating film that is formed on a semiconductor substrate;
selectively etching a portion of the capacitor lower metal to a predetermined depth;
forming a second insulating film over an entire upper surface of the logic metal, the first insulating film, and the etched capacitor lower metal;
forming a capacitor upper metal on the second insulating film in a region corresponding to the etched portion of the etched capacitor lower metal;
forming an interlayer insulating film over an entire upper surface of the second insulating film and the capacitor upper metal;
selectively etching the interlayer insulating film and the second insulating film, thereby forming a first contact hole through which a portion of the capacitor upper metal is exposed, and a second contact hole through which an non-etched portion of the etched capacitor lower metal is exposed; and
filling in the first and second contact holes with a conductive material, thereby forming portions of a metal line.

11. The method according to claim 10, wherein the step of forming the logic metal and the capacitor lower metal comprises:
depositing the logic metal and the capacitor lower metal on the first insulating film in the same process without forming a step structure.

12. The method according to claim 10, wherein the step of forming the capacitor upper metal comprises:
depositing a conductive material over the second insulating film; and
planarizing the conductive material using a CMP process.

13. The method according to claim 12, wherein the capacitor upper metal comprises titanium or titanium nitride.

14. The method according to claim 10, wherein the step of selectively etching a portion of the capacitor lower metal to a predetermined depth comprises:
forming a photoresist pattern on the capacitor lower metal;
etching a portion of the capacitor lower metal to a predetermined depth corresponding to about half of the thickness of the capacitor lower metal using the photoresist pattern as an etch mask; and
removing the photoresist pattern.

15. The method according to claim 10, wherein the step of selectively etching the interlayer insulating film and the second insulating film comprises:
forming a photoresist pattern on the interlayer insulating film that includes openings positioned over a non-etched portion of the etched capacitor lower metal and over a portion of the capacitor upper metal;
etching the interlayer insulating film and the second insulating film using the photoresist pattern as an etch mask, thereby forming a first contact hole through which the portion of the capacitor upper metal is exposed, and a second contact hole through which the non-etched portion of the etched lower metal is exposed.
